(19) United States
(12) Patent Application Publication
(10) Pub. No.: US 2009/0250779 A1
(43) Pub. Date: Oct. 8, 2009

(54) SOLID-STATE IMAGING DEVICE AND MANUFACTURING METHOD THEREOF

(75) Inventors: Yutaka HIROSE, Kyoto (JP); Keisuke TANAKA, Osaka (JP); Shigeru SAITOU, Osaka (JP); Daisuke UEDA, Osaka (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/417,093

(22) Filed: Apr. 2, 2009

(30) Foreign Application Priority Data
Apr. 4, 2008 (JP) 2008-098567

(51) Int. Cl. H01L 31/0232; H01L 21/00

(52) U.S. Cl. 257/432; 438/69; 257/436; 257/E31.127; 257/E21.002

(57) ABSTRACT

A solid-state imaging device in the present invention includes plural photoelectric conversion elements, plural wiring layers, and plural optical waveguide regions each corresponding to and arranged over one of the plural photoelectric conversion elements. A top end of each of the plural optical waveguide regions is higher than a top end of at least one of the plural wiring layers. A bottom end of each of the plural optical waveguide regions is lower than a bottom end of at least one of the plural wiring layers. The plural optical waveguide regions include plural types of optical waveguide regions each having different light absorbing characteristics.

### BACKGROUND OF THE INVENTION

(1) Field of the Invention

The present invention relates to a solid-state imaging device which is capable of optical waveguiding and color separating, and a manufacturing method thereof.

(2) Description of the Related Art

Solid-state imaging devices including MOS sensors and charge coupled devices (CCD) are embedded in digital cameras and cellular phones. Increasing demands for higher definition imaging and further downsizing of the digital cameras and cellular phones lead to miniaturization of the devices, and the pixels (cells) therein. FIG. 1 is a cross-sectional schematic view of a pixel unit of a conventional MOS sensor in a first type. A photoelectric conversion element (photodiode) 102 and a read-out circuit 103, adjacent to the photodiode 102, reading out an output electrical charge provided from the photodiode 102 are formed on the surface of an Si substrate 101. A metal line 105 is formed in an interlayer insulating film 104. Further, a color filter 106 is formed on the interlayer insulating film 104 to receive incident light having a different color for each of pixels. An on-chip lens 107 made of plastic for collecting the incident light on the photodiode 102 is formed on the color filter 106. Here, the pixel itself needs to be downsized in order to miniaturize the pixel. This, however, will result in a decrease in light collection efficiency.

FIG. 2A shows the above observed in a CMOS sensor. FIG. 2A shows dependence of the light collection efficiency on a pixel size which is one of performance indicators of a conventional solid-state imaging device. In FIG. 2A, the abscissa and ordinate respectively represent a cell size (μm) and light collection efficiency. Production of devices not greater than 2 μm in minimum cell size has recently been started. The light collection efficiency of the devices, however, is 50% at highest. Further miniaturization of the devices remaining in similar structures will decrease the light collection efficiency of the devices as small as 1.5 μm in cell size to 45% or less. A smaller cell size causes a distance between an incidence plane of the on-chip lens 107 and the photoelectric conversion element (photodiode) 102; namely an actual light-receiving unit, to be greater than the focal length of the on-chip lens 107. Thus, the above problem results from the fact that a small cell size does not allow the focal length to be long; that is, the incident light cannot be collected on the photodiode 102.

In order to solve the above problem, a second-type conventional technique has been available. The second-type conventional technique, improving the first type, allows a region capable of optical waveguiding to be disposed within a light collectable distance, using an on-chip lens (hereinafter referred to as a waveguide region). The region includes a high-refractive region which is covered with a low-refractive region and formed up to the vicinity of the surface of a photodiode. See Patent References 1-4, for example. FIG. 3 is a cross-sectional schematic view of a pixel unit of a conventional MOS sensor in a second type. Based on the structure of the first-type conventional pixel unit shown in FIG. 1, the second-type conventional pixel unit includes the color filter 106, the photodiode 102, and the interlayer insulating film 104. In the interlayer insulating film 104, disposed below the color filter 106 and above the photodiode 102, is a waveguide region 301 made of a higher-refractive index material (SiNₓ, for example) than the refractive index of the interlayer insulating film (typically, SiO₂) 104. This structure allows the incident light into the waveguide region 301 to be confined in the waveguide region 301, and guided to the photodiode 102 through the waveguide region 301. In other words, a light-collecting loss caused by a short focal length which the on-chip lens 107 has is reduced. The alternate long and short dashed line in FIG. 2A shows the above effect. Compared with the first-type conventional technique, improvement in light collection efficiency with the second-type conventional technique is 5 to 10% when the cell size is no greater than 2 μm.

Patent Reference 1 (U.S. Pat. No. 6,995,442) discloses that a material surrounding the waveguide is intended to be air. Even though no particular rule is formulated as a high-refractive index material for the waveguide, SiNx and SiO₂ are exemplified as the material.

Patent Reference 2 (Japanese Patent 2,869,280) discloses a technique to form an optical waveguide of a charge coupled device.

Patent Reference 3 (Japanese Unexamined Patent Application Publication No. 2007-173258) discloses a technique to form an optical waveguide having a two-tier structure, and incorporate high-refractive index material in each of the tiers.

Patent Reference 4 (Japanese Unexamined Patent Application Publication No. 2007-194606) discloses a technique to form a tapered optical waveguide against an incidence plane in order to enhance light collection efficiency with respect to oblique incidence light, and an opening ratio.

### SUMMARY OF THE INVENTION

Minimizing the cell size to 1.5 μm or smaller significantly lowers the light collection efficiency to 50% or below and makes the solid-state imaging devices impractical even with the second-type conventional technique. It is more impractical with the first-type conventional technique. One of the causes of the problem is that a loss caused by the oblique incidence light cannot be avoided in proportion to the thickness of a color filter provided on each of the waveguide regions.

In order to overcome the problem, a third-type conventional technique is disclosed in Patent Reference 5 (japanese Unexamined Patent Application Publication No. 2001-237405). The third-type conventional technique shows an optical waveguide filled with a color filter material. This conventional technique, however, introduces a color filter using a pigment or dye having a relatively large particle in size. In other words, the particle is as large as a micron-size particle. Thus, it is improbable to evenly fill the color filter material in a minute region equal to 2 μm or smaller in cell size. Further, since a low-refractive region surrounding a waveguide is angled, the optical waveguide cannot be formed between metal lines in a minute cell having a high aspect ratio. This aspect ratio means a ratio of the distance between the photodiode and the lens to the size of the photodiode (the photoelectric conversion element).

The present invention is conceived in view of the above problems and has as an objective to: overcome the problem of lowering light collection efficiency in proportion to the thickness of the color filters which the conventional techniques have introduced; and provide a color imaging device achieving high light collection efficiency in a minute cell.

In order to solve the above problems, a solid-state imaging device, having a plurality of photoelectric conversion elements and a plurality of wiring layers, includes: a plurality of optical waveguide regions each corresponding to and arranged over one of the plurality of photoelectric conversion elements, wherein a top end of each of the plurality of optical waveguide regions is higher than a top end of at least one of the plurality of wiring layers, a bottom end of each of the plurality of optical waveguide regions is lower than a bottom end of at least one of the plurality of wiring layers, and the plurality of optical waveguide regions include a plurality of types of optical waveguide regions each having different light absorbing characteristics. Since this structure causes the waveguide regions themselves to provide excellent color separation characteristics, a conventionally required extra color filter aside from the waveguide regions can be successfully dispensed with. Accordingly, the problem in the conventional technique; that is the lowering light collection efficiency in proportion to the thickness of the color filter layer, can be solved.

Each of the plural optical waveguide regions further includes: a high refractive-index medium which has a refractive index higher than a refractive index of a surrounding of the high refractive-index medium, and allows 50% or greater of a light of a light-transmitting wavelength region to transmit; and light absorbing particles each of which includes metal and has a particle diameter between 5 nm and 50 nm, the light absorbing particles being dispersed in the high refractive-index medium in order to define the light absorbing characteristic. This structure can realize a waveguide having excellent color separation characteristics acquired by plasmon absorption caused by coupling surface plasmon of particles including metal with a small grain diameter and visible light, plasmon absorption of metal, and electronic transition absorption of a metal oxide.

The high refractive-index medium is made of an inorganic material, and the light absorbing particles are made of another inorganic material.
This structure can prevent the light absorbing characteristics from degrading due to aged deterioration, and constantly maintain excellent color reproducibility. The high refractive-index medium is made of an organic material, and the light absorbing particles are made of another organic material. This structure can realize a simplified manufacturing process and reduction of manufacturing costs even though possibly causing a degradation of the light absorbing characteristics due to aged deterioration.

The high refractive-index medium includes: a medium made of a polymeric material including at least either carbon or silicon, and high refractive-index particles each having a particle diameter between 5 nm and 100 nm, the high refractive-index particles being dispersed in the high refractive-index medium, and made of a material different from a material of the light absorbing particles. This structure allows the high refractive-index particles to serve as a high refractive-index medium with the refractive index of the medium enhanced. As a result, the high refractive-index medium can be filled in a micro-space, formed over the photodiodes each including a corresponding pixel, leaving no air-gap or causing any stress therein. Moreover, the light absorbing particles can be uniformly dispersed in the high refractive-index medium. Hence, excellent color reproducibility free from a variation in color among pixels can be realized.

The high refractive-index medium includes particles each having a particle diameter between 5 nm and 100 nm and being dispersed in the high refractive-index medium, the particles being made of a metal oxide of which material is different from the material of the light absorbing particles. This structure allows the high refractive-index particles to serve as a high refractive-index medium with the refractive index of the medium enhanced. As a result, the high refractive-index medium can be filled in a micro-space, formed over the photodiodes each including a corresponding pixel, leaving no air-gap or causing any stress therein. In addition, the light absorbing particles can be uniformly dispersed in the high refractive-index medium. Hence, excellent color reproducibility free from a variation in color among pixels can be realized.

The plurality of optical waveguide regions include a first-type, a second-type, and a third-type of optical waveguide regions, the first-type of optical waveguide region includes at least one of gold particles, copper particles, chromium particles, and iron-chromium oxide particles as the light absorbing particles, the second-type of optical waveguide region includes at least one of cobalt-titanium oxide particles, nickel-titanium-zinc oxide particles, and cobalt-zinc oxide particles as the light absorbing particles, and the third-type of optical waveguide region includes at least one of cobalt-aluminum oxide particles, and cobalt-chromium oxide particles as the light absorbing particles. This structure can provide a transmission filter mainly for: a red region by using the dispersed light absorbing particles included in the first optical waveguide; a green region by using the dispersed light absorbing particles included in the second optical waveguide; and a blue region by using the dispersed light absorbing particles included in the third optical waveguide. In addition, mixing the dispersed light absorbing particles included in the first, second and third optical waveguides, and selecting a ratio of the mixing can realize color characteristics in any given region.

Here, the plural optical waveguide regions include a first-type, a second-type, and a third-type of optical waveguide regions, the first-type of optical waveguide region includes anthraquinone molecules as the light absorbing particles, the second-type of optical waveguide region includes copper-phthalocyanine chloride bromide particles as the light absorbing particles, and the third-type of optical waveguide region includes E -type copper phthalocyanine particles as the light absorbing particles. This structure can provide a transmission filter mainly for: a red region by using the dispersed light absorbing particles included in the first optical waveguide; a green region by using the dispersed light absorbing particles included in the second optical waveguide; and a blue region by using the dispersed light absorbing particles included in the third optical waveguide. In addition, mixing the dispersed light absorbing particles included in the first, second and third optical waveguides, and selecting a ratio of the mixing can realize color characteristics in any given region.

The light absorbing particles, provided in at least one of the plural types of optical waveguide regions, include organic molecules. This structure can provide a waveguide having excellent color separation characteristics thanks to the characteristics of organic molecules showing absorption transmission characteristics only for a particular wavelength of visible light.

The solid-state imaging device further includes read circuits each of which reads out a signal charge from one of the plural photoelectric conversion elements, wherein an insulating region is formed: between the plural optical waveguide regions and the plural of photoelectric conversion elements; and between said plural optical waveguide regions and said read circuit. This structure can ensure to prevent the waveguide regions including the metal particles from establishing an electrical connection with either the photoelectric conversion elements or the circuit region.

Further, a manufacturing method of the solid-state imaging device in the present invention, devised in accordance with the above described solid-state imaging device, offers a similar effect.

As described above, the present invention, acquiring a color filter function in waveguide regions, can realize a solid-state imaging device which eliminates a loss caused by the oblique incidence light in proportion to the thickness of the color filters, and includes a color filter having microscopic pixels to realize highlight collection efficiency with high color reproducibility provided. Hence, the present invention achieves a significant practical value since the market has recently desires compact and thin model digital cameras.

### FURTHER INFORMATION ABOUT TECHNICAL BACKGROUND TO THIS APPLICATION

The disclosure of Japanese Patent Application No. 2008-098567 filed on Apr. 4, 2008 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a cross-sectional schematic view of a pixel unit of a solid-state imaging device in a first-type conventional technique;

FIG. 2A shows dependence of the light collection efficiency on a pixel size which is one of performance indicators of a conventional solid-state imaging device;

FIG. 2B shows dependence of the light collection efficiency on a pixel size which is one of performance indicators of a conventional solid-state imaging device and a solid-state imaging device in the present invention;

FIG. 3 is a cross-sectional schematic view of a pixel unit of a solid-state imaging device in a second-type conventional technique;

FIG. 4A is a cross-sectional schematic view of a pixel unit of a solid-state imaging device in a first embodiment of the present invention;

FIG. 4B is a cross-sectional schematic view of a pixel unit in a modification example of the solid-state imaging device in the first embodiment of the present invention;

FIG. 5 shows color separation characteristics of the solid-state imaging device in the first embodiment of the present invention;

FIG. 6 shows a schematic view of a process of the solid-state imaging device in the first embodiment of the present invention in a manufacturing process before forming waveguides;

FIG. 7 shows a schematic view of a forming process of a red-transmitting optical waveguide of the solid-state imaging device in the first embodiment of the present invention;

FIG. 8 shows a schematic view of a forming process of a green-transmitting optical waveguide of the solid-state imaging device in the first embodiment of the present invention;

FIG. 9 shows a schematic view of a forming process of a blue-transmitting optical waveguide of the solid-state imaging device in the first embodiment of the present invention;

FIG. 10 shows a schematic view of a process of the solid-state imaging device in the first embodiment of the present invention in a manufacturing process after forming the waveguides;

FIG. 11 is a cross-sectional schematic view of a pixel unit of a solid-state imaging device in a second embodiment of the present invention;

FIG. 12 shows color separation characteristics of the solid-state imaging device in the second embodiment of the present invention;

FIG. 13 shows a schematic view of a forming process of a red-transmitting optical waveguide of the solid-state imaging device in the second embodiment of the present invention;

FIG. 14 shows a schematic view of a forming process of a green-transmitting optical waveguide of the solid-state imaging device in the second embodiment of the present invention;

FIG. 15 shows a schematic view of a forming process of a blue-transmitting optical waveguide of the solid-state imaging device in the second embodiment of the present invention;

FIG. 16 shows a schematic view of a process of the solid-state imaging device in the first embodiment of the present invention in a manufacturing process after forming the waveguides;

FIG. 17 shows cross-sectional views of three pixel units in red, green, and blue in the solid-state imaging device of a third embodiment of the present invention;

FIG. 18 shows sensitivity characteristics of the solid-state imaging device in the third embodiment of the present invention;

FIG. 19 shows a schematic view of a process of the solid-state imaging device in the third embodiment of the present invention in a manufacturing process before forming waveguides;

FIG. 20 shows a schematic view of a forming process of a red-transmitting optical waveguide of the solid-state imaging device in the third embodiment of the present invention;

FIG. 21 shows a schematic view of a forming process of a green-transmitting optical waveguide of the solid-state imaging device in the third embodiment of the present invention;

FIG. 22 shows a schematic view of a forming process of a blue-transmitting optical waveguide of the solid-state imaging device in the third embodiment of the present invention; and

FIG. 23 shows a schematic view of a process of the solid-state imaging device in the third embodiment of the present invention in a manufacturing process after forming the waveguides.

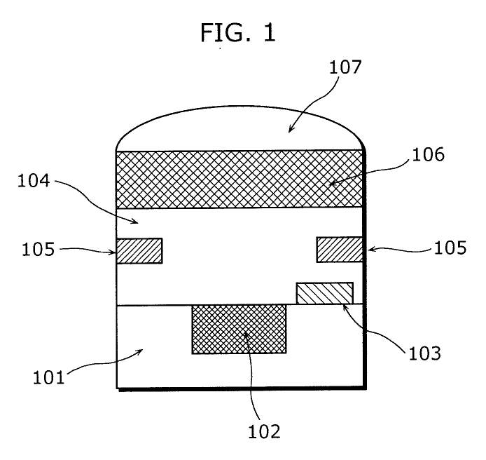

### DESCRIPTION OF THE PREFERRED EMBODIMENTS

Hereinafter, embodiments of the present invention shall be described in detail with reference to the drawings. Only exemplary embodiments of the present invention have been described in detail above. However, those skilled in the art will readily appreciate that many modifications are possible in the exemplary embodiment without materially departing from the novel teachings and advantages of this invention, and therefore, all such modifications are intended to be included within the scope of this invention.

A solid-state imaging device in the present invention includes plural photoelectric conversion elements, plural wiring layers, and plural optical waveguide regions each corresponding to and arranged over one of the plurality of photoelectric conversion elements. Here, a top end of each of the plurality of optical waveguide regions is higher than a top end of at least one of the plural wiring layers, a bottom end of each of the plurality of optical waveguide regions is lower than a bottom end of at least one of the plurality of wiring layers, and the plural optical waveguide regions include plural types of optical waveguide regions each having different light absorbing characteristics. Further, each of the plural optical waveguide regions further includes: a high refractive-index medium which has a refractive index higher than a refractive index of a surrounding of the high refractive-index medium, and allows 50% or greater of a light of a light-transmitting wavelength region to be transmitted; and light absorbing particles each of which includes metal and has a particle diameter between 5 nm and 50 nm, the light absorbing particles being dispersed in the high refractive-index medium in order to define the light absorbing characteristic.

This structure permits each of the plural optical waveguide regions functions as a waveguide, as well as a color filter. The solid-state imaging device in the present invention eliminates the needs for an extra color filter layer aside from the optical waveguide region. Thus, the solid-state imaging device can improve light collection efficiency even though the cell size is as small as 2 μm. Further, the high refractive-index medium which allows 50% or greater of a light of a light-transmitting wavelength region to be transmitted is preferably a transparent medium which allows 70% or greater of the light to be transmitted.

### First Embodiment

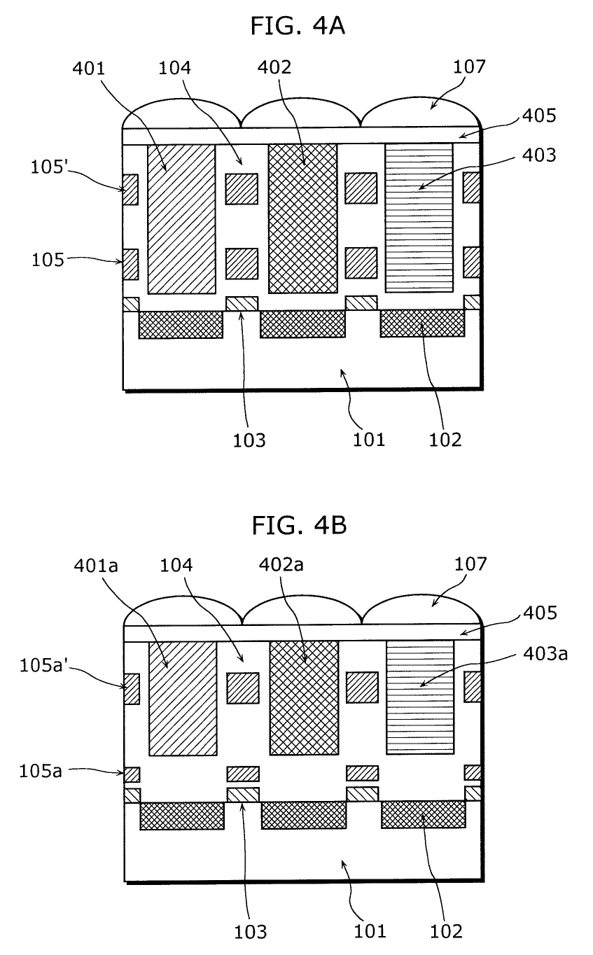

A solid-state imaging device in a first embodiment of the present invention and a manufacturing method thereof shall be described with reference to FIGS. 4A through 10.

FIG. 4A illustrates cross-sectional views of three pixel units in red, green, and blue in the solid-state imaging device of the embodiment. FIG. 4A shows that a photodiode 102, a read-out circuit 103 reading out an output signal from the photodiode 102, and metal lines 105 and 105′ are formed in each of pixel units on a surface of an Si substrate 101. The metal lines 105 and 105′ are provided in an interlayer insulating film 104 chiefly made of SiO₂. Each of the pixel units is 1.5 μm in size. In a portion of the interlayer insulating film 104 on each of photodiodes 104, an optical waveguide 401, an optical waveguide 402, and an optical waveguide 403 are formed. The optical waveguide 401 transmits a red wavelength region light, and absorbs the lights of the other wavelength regions. The optical waveguide 402 transmits a green wavelength region light, and absorbs the lights of the other wavelength regions. The optical waveguide 403 transmits a blue wavelength region light, and absorbs the lights of the other wavelength regions. On each of the optical waveguides 401, 402, and 403, a planarization insulating film 405 transmitting light 100% is formed. Further, on the surface of the planarization insulating film 405, a micro lens 107 is provided. Here, the distance between the surface of the photodiode and the undersurface of the micro lens 107 is 2.75 μm. Such an aspect of the cell cannot efficiently collect incident light in each of the pixels due to diffraction limit in a typical optical system without the waveguides described in the first embodiment. Here, each of the optical waveguides 401, 402, and 403 which is made of a polyimide resin medium of which host resin medium as a high-refractive index medium includes polybenzoxazoles has a refractive index (1.85) higher than the refractive index of SiO₂ surrounding the optical waveguides 401, 402, and 403 (1.45), and transmits 50% or greater of a light in each of light-intercepting wavelength regions. Thus, the optical waveguides 401, 402, and 403 can efficiently confine the incident lights therein and waveguide the incident lights to the associated photodiodes 102.

Further, the polyimide resin medium, a base material for each of the waveguides 401, 402, and 403, includes dispersed titanium oxide particles, each having a particle diameter between 5 nm and 100 nm (median: 75 nm), served as particles providing a high-refractive index in order to enhance a refractive index.

In addition, the optical waveguides 401, 402, and 403 have dispersed light absorbing particles, each having a particle diameter between 5 nm and 50 nm, including metal to define light absorbing characteristics of each of the optical waveguides 401, 402, and 403. The optical waveguide 401, transmitting a red wavelength, includes gold particles, each having a particle diameter between 5 nm and 50 nm (median: 15 nm), served as dispersing particles (light absorbing particles). The optical waveguide 402, transmitting a green wavelength, includes dispersed cobalt-titan-nickel-zinc oxide particles each having a particle diameter between 5 nm and 50 nm (median: 25 nm) in particle diameter. The optical waveguide 403, transmitting a blue wavelength, includes cobalt-aluminum oxide particles each having a particle diameter between 5 nm and 50 nm (median: 20 nm).

Here each of the waveguides 401, 402, and 403 shows slight electrical conductivity (10 kΩ to 1 MΩ) since including the metal particles. Hence, the waveguides 401, 402, and 403 are preferably insulated from the metal lines 105 and 105′ via the interlayer insulating film 104. In addition, the waveguides 401, 402, and 403 are preferably insulated from the photodiodes 102, as well. The embodiment sees the waveguides 401, 402, and 403 insulated via the interlayer insulating film 104.

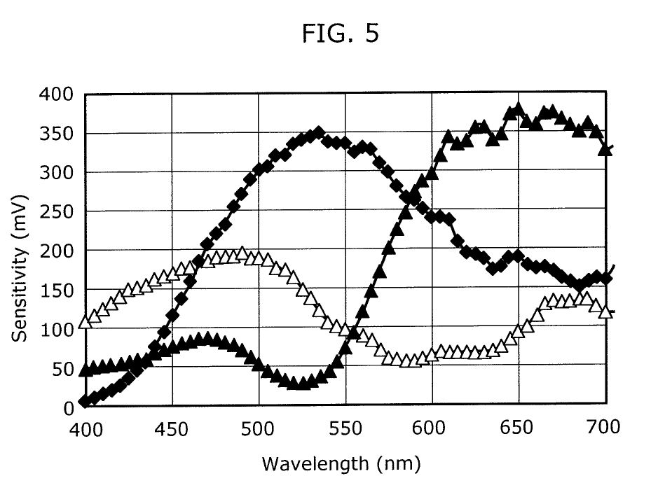

FIG. 5 shows sensitivity characteristics of the solid-state imaging device in the embodiment. This embodiment can realize excellent color separation characteristics in red, green, and, blue regions.

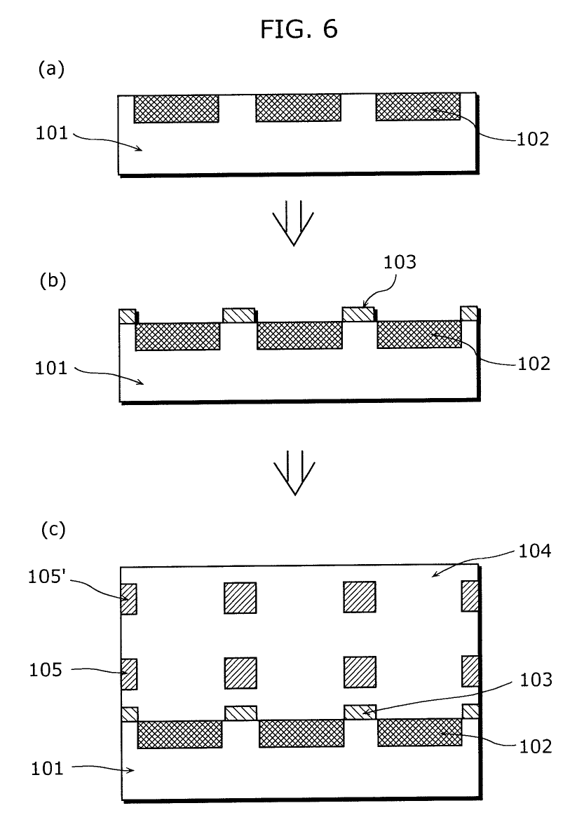

(FIGS. 6 through 10: Manufacturing Method)

The following describes a manufacturing process of the solid-state imaging device in the embodiment with reference to FIGS. 6 through 10. As shown in FIG. 6(a), the photodiode 102 is formed, for each of the pixels, on the Si substrate 101. Next, as shown in FIG. 6(b), a region for the read-out circuit 103 is formed. Then, as shown in FIG. 6(c), the metal lines 105 and 105′ are formed in the interlayer insulating film 104 made of SiO₂.

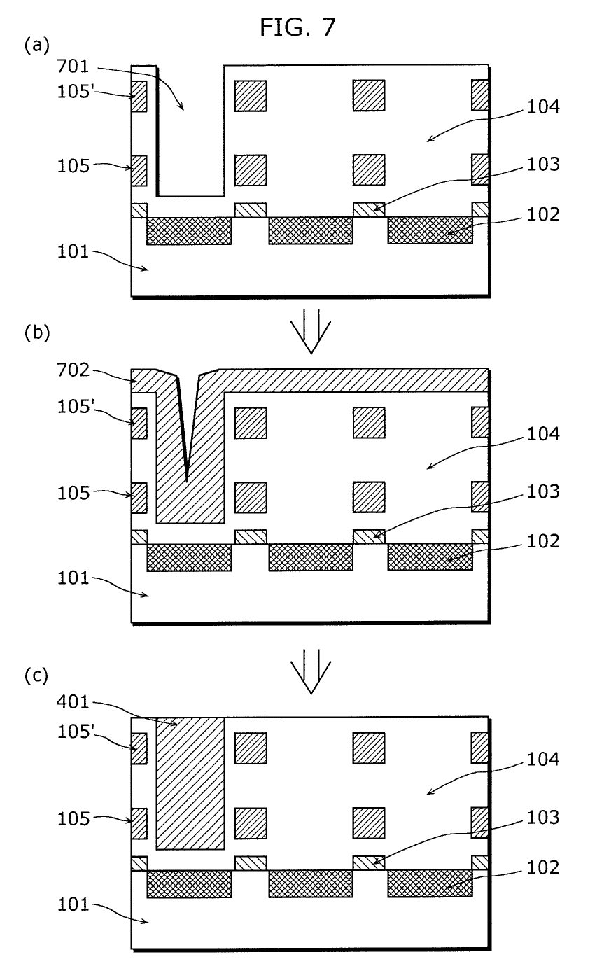

Next, as shown in FIG. 7(a), an opening 701 is formed by dry etching in a red-transmitting optical waveguide forming region above the photodiode 102 including a red pixel. Then, the host resin medium and a solvent with the gold particles dispersed are applied with a spin-coating technique, and annealing is provided at 200° C. Since the opening 701 has a high aspect ratio, this process is repeated twice to completely fill the opening 701 with an annealed object 702. Then, the surface layer is removed by surface polishing to form the red-transmitting optical waveguide 401 as shown in FIG. 7(c).

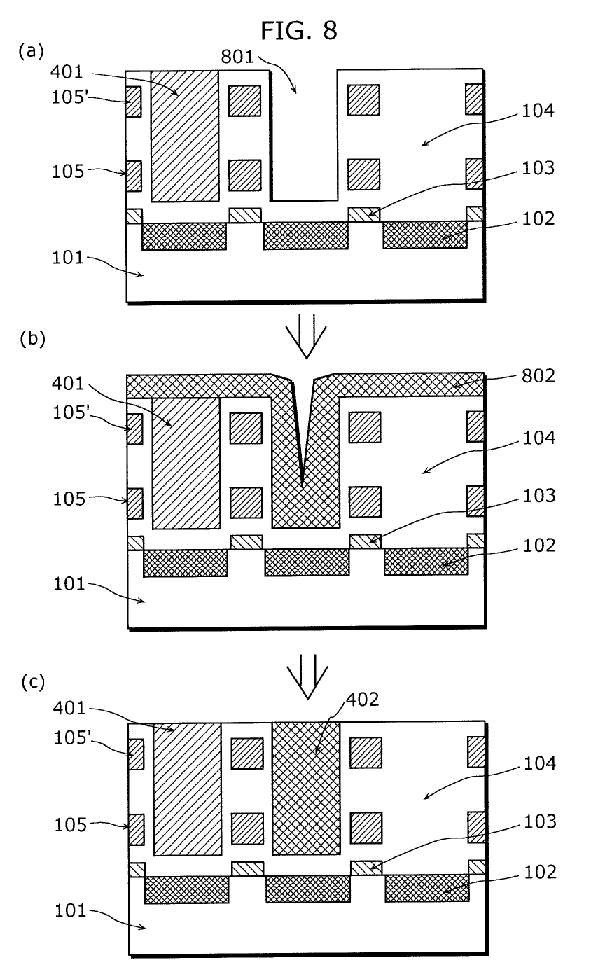

Next, as shown in FIG. 8(a), an opening 801 is formed by dry etching in a green-transmitting optical waveguide forming region above the photodiode 102 including a green pixel. Then, the host resin medium and a solvent having dispersed cobalt-titan-nickel-zinc oxides are applied to the opening 801 with the spin-coating technique, and sintering is provided at 200° C. Since the opening 801 has a high aspect ratio, this process is repeated twice to completely fill the opening 801 with a sintered object 802. Then, the surface layer is removed by surface polishing to form the green-transmitting optical waveguide 402 as shown in FIG. 8(c).

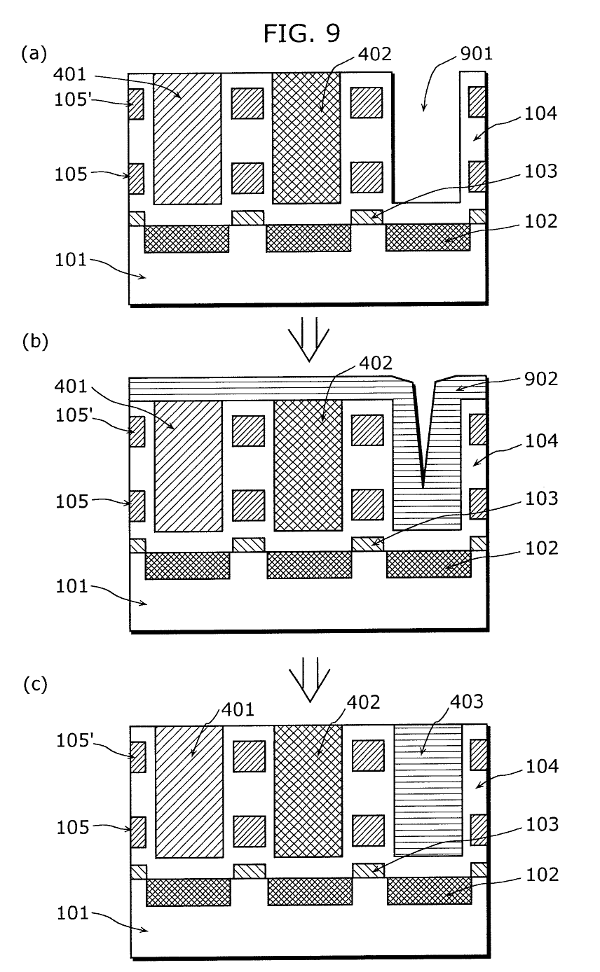

Next, as shown in FIG. 9(a), an opening 901 is formed by dry etching in a blue-transmitting optical waveguide forming region above the photodiode 102 including a blue pixel. Then, the host resin medium and a solvent having dispersed cobalt-aluminum oxides are applied to the opening 901 with the spin-coating technique, and sintering is provided at 200° C. Since the opening 901 has a high aspect ratio, this process is repeated twice to completely fill the opening 901 with a sintered object 902. Then, the surface layer is removed by surface polishing to form the green-transmitting optical waveguide 403 as shown in FIG. 9(c).

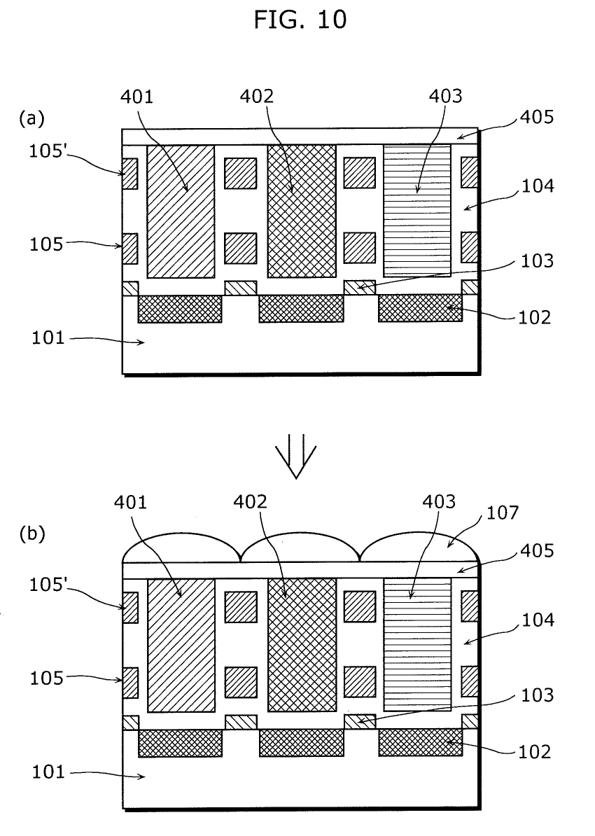

Next, as shown in FIG. 10(a), the planarization insulating film 405 is formed on the outermost surface. After the surface of the planarization insulating film 405 is planarized, as shown in FIG. 10(b), the micro lenses 107 are formed on an outermost surface of the planarization insulating film 405.

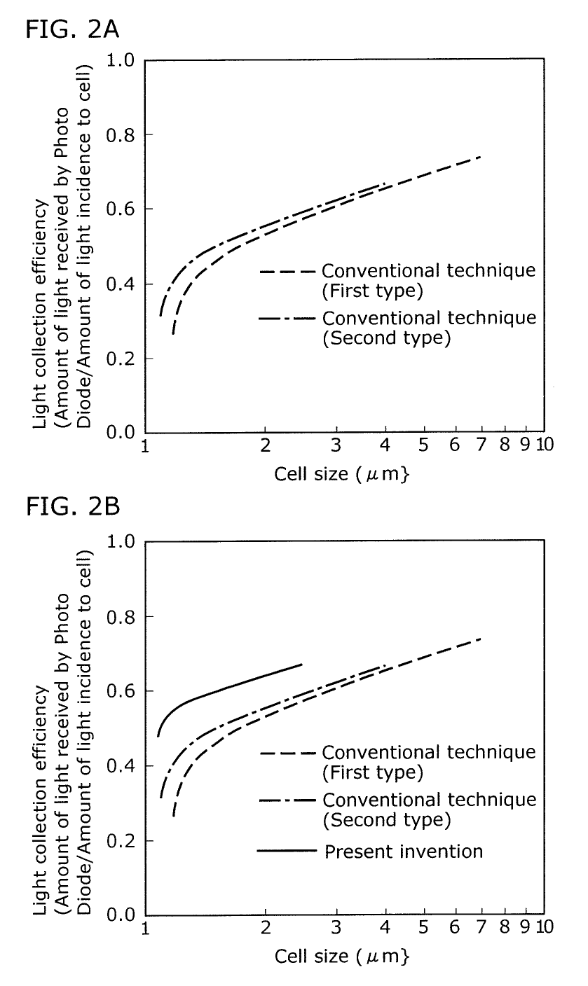

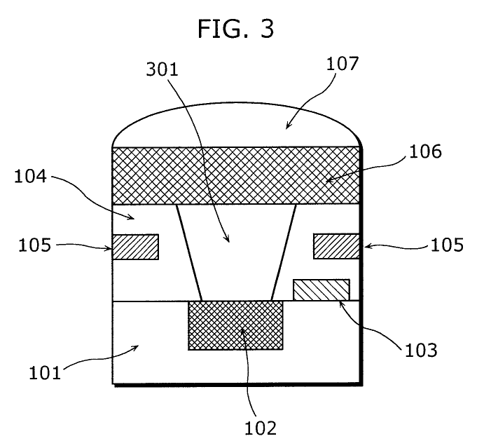

FIG. 2B shows the dependence of the light collection efficiency on a pixel size, which is one of performance indicators of the solid-state imaging device in the present invention and a conventional solid-state imaging device. In FIG. 2B, the abscissa and ordinate respectively represent a cell size (μm) and light collection efficiency. The light collection efficiency, represented in a full line, of the solid-state imaging device in the present invention has approximately a dozen percent of improvement with the cell size 2 μm or smaller, compared with the light collection efficiency, represented in a broken line, of the solid-state imaging device in a conventional technique.

FIG. 4B is a cross-sectional schematic view of the solid-state imaging device as a modification example of the first embodiment of the present invention. In this modification example, the wiring layer includes three layers as observed in the first embodiment. Here, the bottom layer and the second layer from the bottom are formed on a plane closer to the semiconductor substrate than the bottom layer and the second layer from the bottom in the first embodiment are formed. Thus, the distance between the surface of the photodiode 102 and the micro lens 107 can be reduced by 10% This allows the waveguides 401a, 402a, and 403a to be formed down to a position above the top end of the metal lines 105a and below the bottom end of the metal lines 105a′. This structure provides approximately 20% of improvement in light collection efficiency, compared with a structure without a waveguide.

It is noted that the polyimide resin is used as the host resin; instead, an acrylic resin, an epoxy resin, a polyester resin, and a polyolefin resin may also be used.

### Second Embodiment

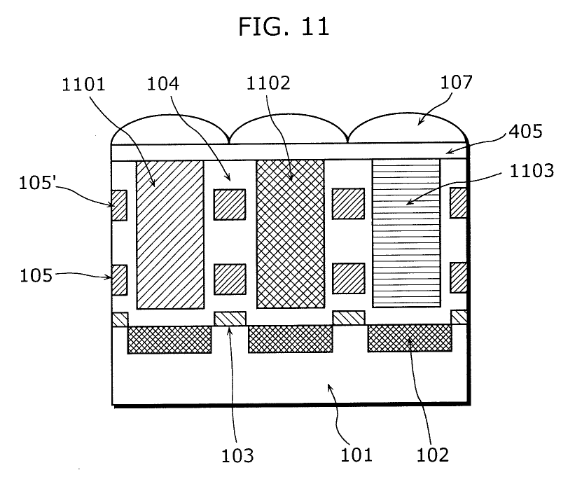

A solid-state imaging device in a second embodiment of the present invention and a manufacturing method thereof shall be described with reference to FIG. 11 through FIG. 16.

FIG. 11 illustrates cross-sectional views of three pixel units in red, green, and blue in the solid-state imaging device of the embodiment. FIG. 11 shows that the photodiode 102, an output signal read-out circuit 103 thereof, and metal lines 105 and 105′ are formed in each of pixel units on a surface of an Si substrate 101. The metal lines 105 and 105′ are provided in an interlayer insulating film 104 chiefly made of SiO₂. Each of the pixels is 1.5 μm in size. In a portion of the interlayer insulating film 104 on each of photodiodes 102, an optical waveguide 1101, an optical waveguide 1102, and an optical waveguide 1103 are formed. The optical waveguide 1101 transmits a red wavelength region light and absorbs the lights of the other wavelength regions. The optical waveguide 1102 transmits a green wavelength region light and absorbs the lights of the other wavelength regions. The optical waveguide 1103 transmits a blue wavelength region light and absorbs the lights of the other wavelength regions. On each of the optical waveguides 1101, 1102, and 1103, the planarization insulating film 405 transmitting light 100% is formed. Further, on the surface of the planarization insulating film 405, the micro lens 107 is provided. Here, the distance between the surface of the photodiode and the undersurface of the micro lens 107 is 2.75 μm. Having such an aspect of the cell, a typical optical system without the waveguides described in the second embodiment cannot efficiently collect incident light into each of the pixels due to diffraction limit. Here, each of the optical waveguides 1101, 1102, and 1103 which is made of a polyimide resin medium including polybenzoxazoles has a refractive index (1.85) higher than the refractive index of SiO₂ surrounding the optical waveguides 1101, 1102, and 1103 (1.45), and transmits 50% or greater of a light in each of light-intercepting wavelength regions. Thus, the optical waveguides 1101, 1102, and 1103 can efficiently confine the incident lights therein and waveguide the incident lights into the associated photodiodes 102.

Further, the polyimide resin medium, a base material for each of the waveguides 1101, 1102, and 1103, includes dispersed titanium oxide particles in order to enhance a refractive index, each of oxide particles which varies between 5 nm and 100 nm (median: 75 nm).

Here, the optical waveguide 1101, transmitting a red wavelength, includes particles having anthraquinone (PR177) molecules, each of the particles which varies between 20 nm and 100 nm in particle diameter (median: 50 nm), and serves as dispersing particles. The optical waveguide 1102, transmitting a green wavelength, includes dispersed particles having copper phthalocyanine chloride bromide, each of the particles which varies between 20 nm and 100 nm (median: 75 nm) in particle diameter. The optical waveguide 1103, transmitting a blue wavelength, includes dispersed particles having ε-type copper phthalocyanine, each of the particles which varies between 20 nm and 100 nm (median: 20 nm) in particle diameter.

Here each of the waveguides 1101, 1102, and 1103 shows slight electrical conductivity (100 kΩ to 1 MΩ) since including particles having conductive polymer molecules. Hence, the waveguides 1101, 1102, and 1103 are preferably insulated from the metal lines 105, and 105′ via the interlayer insulating film 104. In addition, the waveguides 1101, 1102, and 1103 are preferably insulated from the photodiodes 102, as well. The embodiment sees the waveguides 1101, 1102, and 1103 insulated via the interlayer insulating film 104.

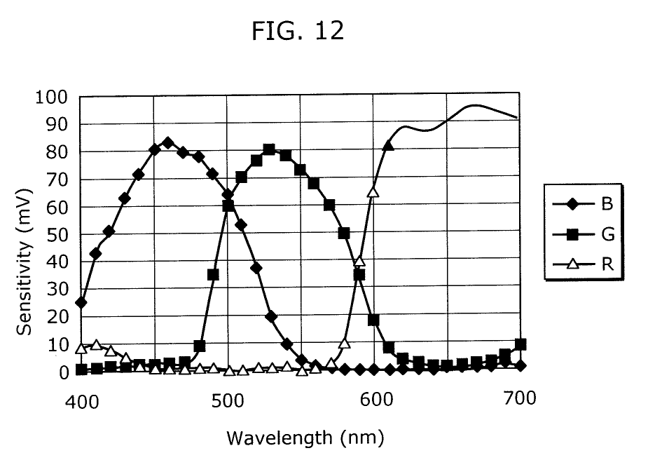

FIG. 12 shows sensitivity characteristics of the solid-state imaging device in the embodiment. This embodiment can realize excellent color separation characteristics in red, green, and, blue regions.

(FIGS. 6 and 13 through 16: Manufacturing Method)

The following describes a manufacturing process of the solid-state imaging device in the embodiment with reference to FIGS. 6, and 13 through 16. Similar to the first embodiment, a photodiode region is formed, for each of the pixels, on the Si substrate 101, as shown in FIG. 6(a). Next, as shown in FIG. 6(b), a region for the read-out circuit 103 from the photodiode 102 is formed. Then, as shown in FIG. 6(c), the metal lines 105, and 105′ are formed in the interlayer insulating film 104 made of SiO₂.

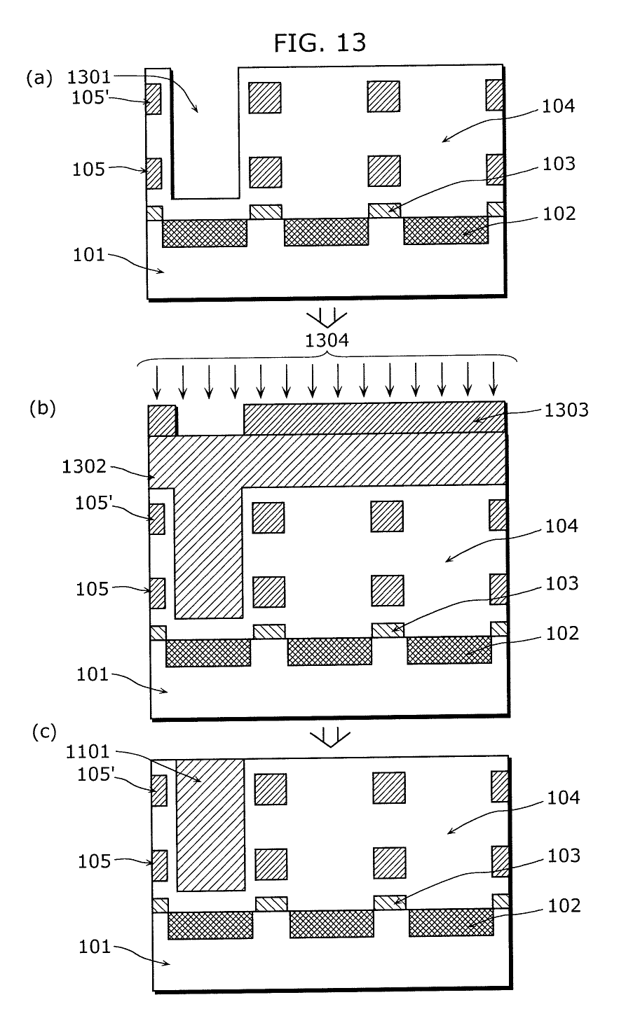

Next, as shown in FIG. 13(a), an opening 1301 is formed by dry etching in a red-transmitting optical waveguide forming region above the photodiode 102 including a red pixel. Then, the host resin medium and a solvent including dispersed particles having anthraquinone molecules are applied to the opening 1301 with the spin-coating technique, and sintering is provided at 100° C. After the opening 1301 is completely filled with a sintered object 1302, the other regions than the red-transmitting optical waveguide forming region are photo-shielded by a mask 1303, and the red-transmitting optical waveguide forming region is exposed, using an i-ray 1304. The resin in the exposed part cures since a part of the polymer molecules is polymerized. Meanwhile, the photo-shaded part which does not cure separates by developer. Planarization provided on the surface, as shown in FIG. 13(c), leads to a completion of the red-transmitting optical waveguide 1101.

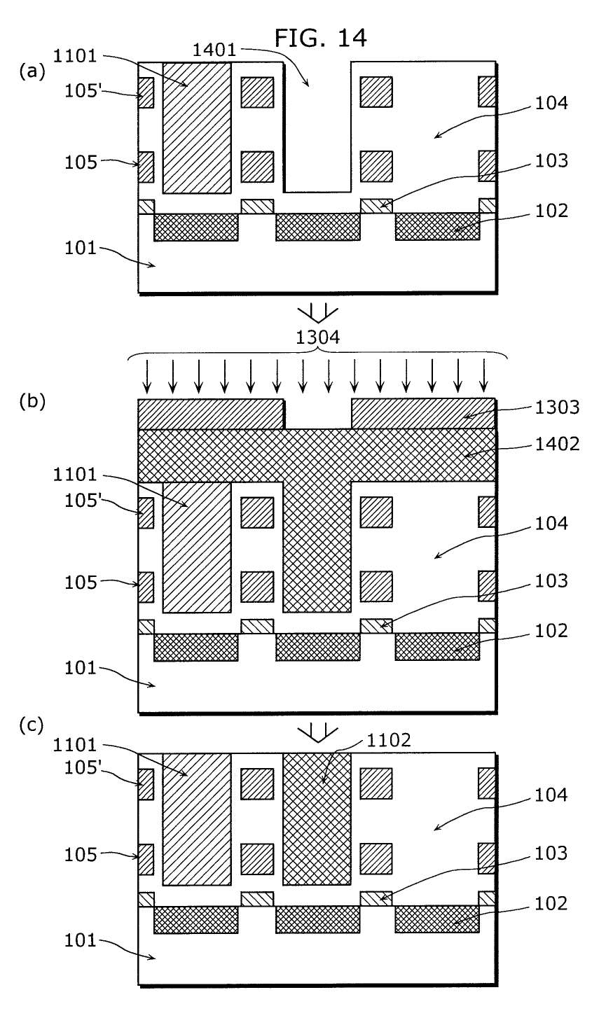

Similarly, as shown in FIG. 14(a), an opening 1401 is formed by dry etching in a green-transmitting optical waveguide forming region above the photodiode 102 including a green pixel. Next, the host resin medium and a solvent including dispersed particles having the copper phthalocyanine chloride bromide molecules are applied to the opening 1401, and sintering is provided at 200° C. After the opening 1401 is completely filled with a sintered object 1402, the other regions than the green-transmitting optical waveguide forming region are photo-shielded by the mask 1303, and the green-transmitting optical waveguide forming region is exposed, using the i-ray 1304. The resin in the exposed part cures since a part of the polymer molecules is polymerized. Meanwhile, the photo-shaded part which does not cure separates by developer. Planarization on the surface of the interlayer insulating film 104 leads to a completion of the green-transmitting optical waveguide 1102, as shown in FIG. 14(c).

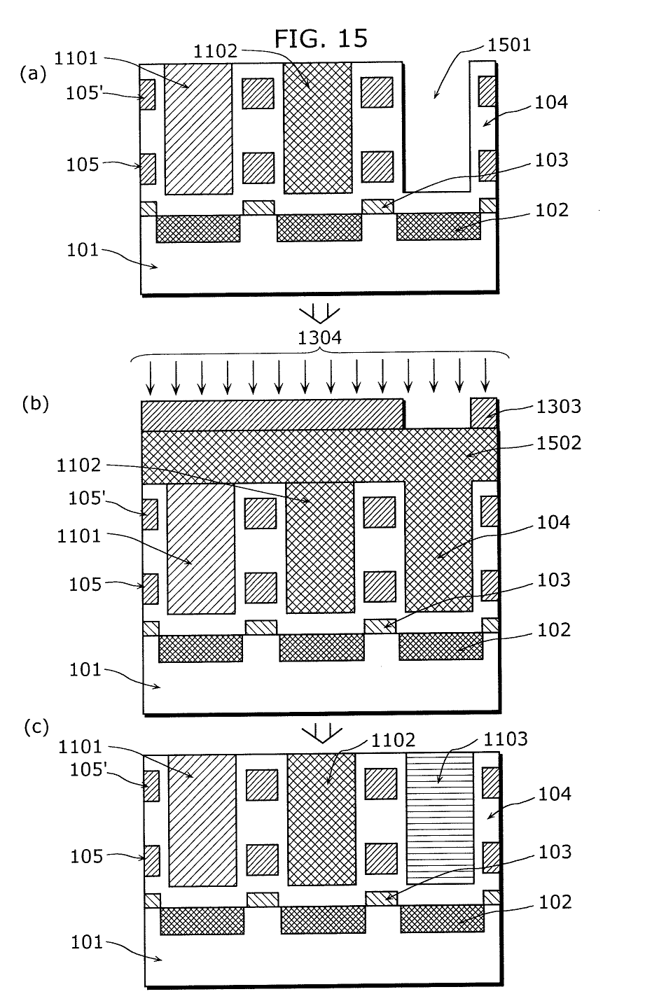

Similarly, as shown in FIG. 15(a), an opening 1501 is formed by dry etching in a blue-transmitting optical waveguide forming region above the photodiode 1501 including a blue pixel. Then, the host resin medium and a solvent including dispersed particles having E-type copper phthalocyanine are applied to the opening 1501 with the spin-coating technique, and sintering is provided at 100° C. Here, each of the dispersed particles varies between 5 nm and 50 nm (median: 20 nm) in particle diameter. After the opening 1502 is completely filled with a sintered object 1502, the other regions than the blue-transmitting optical waveguide forming region are photo-shielded by the mask 1203, and the blue-transmitting optical waveguide forming region is exposed, using the i-ray 1204. The resin in the exposed part cures since a part of the polymer molecules is polymerized. Meanwhile, the photo-shaded part which does not cure separates by developer. Planarization provided on the surface, as shown in FIG. 14(c), leads to a completion of the blue-transmitting optical waveguide 1103.

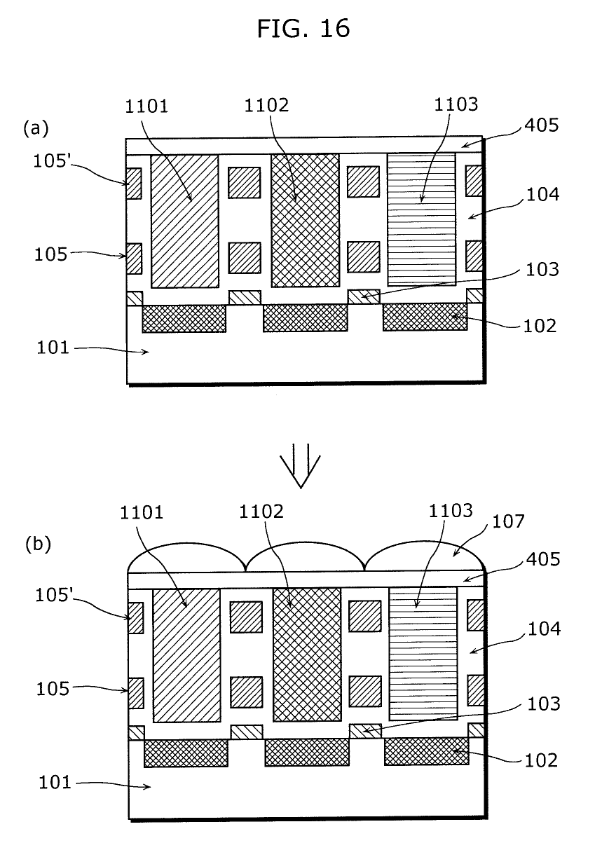

Next, as shown in FIG. 16(a), the planarization insulating film 405 is formed on an outermost surface. After the surface of the planarization insulating film 405 is planarized, as shown in FIG. 16(b), the micro lenses 107 are formed on an outermost surface of the planarization insulating film 405.

It is noted that the polyimide resin is used as the host resin; instead, an acrylic resin, an epoxy resin, a polyester resin, and a polyolefin resin may also be used.

### Third Embodiment

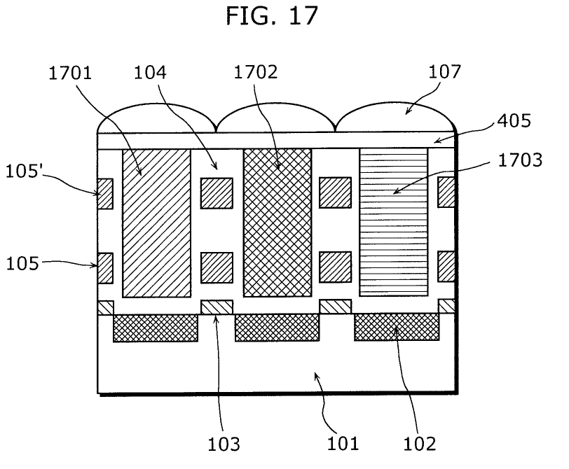

A solid-state imaging device in a third embodiment of the present invention and a manufacturing method thereof shall be described with reference to FIGS. 17 through FIG. 23.

FIG. 17 illustrates cross-sectional views of three pixel units in red, green, and blue in the solid-state imaging device of the embodiment. FIG. 17 shows that the photodiode 102, the output signal read-out circuit 103 thereof, and the metal lines 105 and 105′ are formed in each of pixel units on a surface of the Si substrate 101. The metal lines 105 and 105′ are provided in the interlayer insulating film 104 chiefly made of SiO₂. Each of the pixels is 1.5 μm in size. In a portion of the interlayer insulating film 104 on each of photodiodes 102, an optical waveguide 1701, an optical waveguide 1702, and an optical waveguide 1703 are formed. The optical waveguide 1701 transmits a red wavelength region light and absorbs the lights of the other wavelength regions. The optical waveguide 1702 transmits a green wavelength region light and absorbs the lights of the other wavelength regions. The optical waveguide 1703 transmits a blue wavelength region light and absorbs the lights of the other wavelength regions. On each of the optical waveguides 1701, 1702, and 1703, the planarization insulating film 405 transmitting light 100% is formed. Further, on the surface of the planarization insulating film 405, the micro lens 107 is provided. Here, the distance between the surface of the photodiode and the undersurface of the micro lens 107 is 2.75 μm. Having such an aspect of the cell, a typical optical system without the waveguides described in the third embodiment cannot efficiently collect incident light into each of the pixels due to diffraction limit. Here, each of the optical waveguides 1701, 1702, and 1703 includes oxide silicon glass having dispersed oxide titanium particles each varies between 5 nm and 100 nm (median: 75 nm). Since the optical waveguides 1701, 1702, and 1703 enjoy a refractive index (1.65) higher than a refractive index of SiO₂ (1.45) surrounding the optical waveguides, and are insulating materials having a wide bandgap, 90% of a light in each of light-intercepting wavelength regions transmits through. Thus, the optical waveguides 1701, 1702, and 1703 can efficiently confine the incident lights therein and waveguide the incident lights into the associated photodiodes 102.

Further, the optical waveguide 1701, transmitting a red wavelength, includes gold particles, each having a particle diameter between 5 nm and 50 nm (median: 15 nm), served as dispersing particles. The optical waveguide 1702, transmitting a green wavelength, includes dispersed cobalt-titan-nickel-zinc oxides each having a particle diameter between 5 nm and 50 nm (median: 25 nm). The optical waveguide 1703, transmitting a blue wavelength, includes cobalt-aluminum oxides each having a particle diameter between 5 nm and 50 nm (median: 20 nm).

Here, each of the waveguides 1701, 1702, and 1703 shows slight electrical conductivity (10 kΩ to 1 MΩ) since including metal particles. Hence, the waveguides 1701, 1702, and 1703 are preferably insulated from the metal lines 105, and 105′ via the interlayer insulating film 104. In addition, the waveguides 1701, 1702, and 1703 are preferably insulated from the photodiodes 102, as well. The embodiment sees the waveguides 1101, 1102, and 1103 insulated via the interlayer insulating film 104.

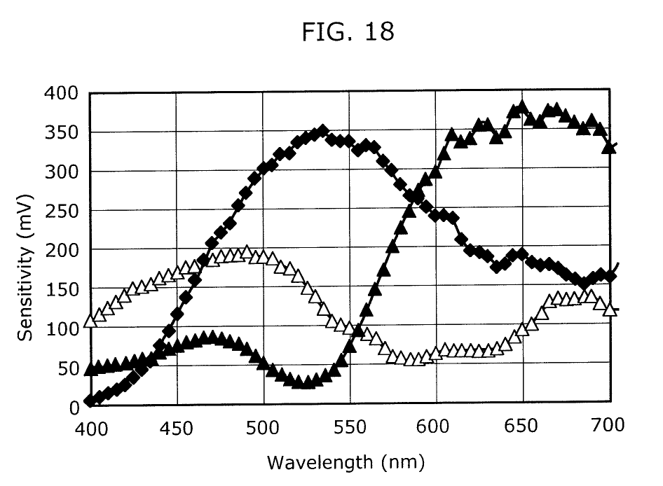

FIG. 18 shows sensitivity characteristics of the solid-state imaging device in the embodiment. This embodiment can realize excellent color separation characteristics in red, green, and, blue regions.

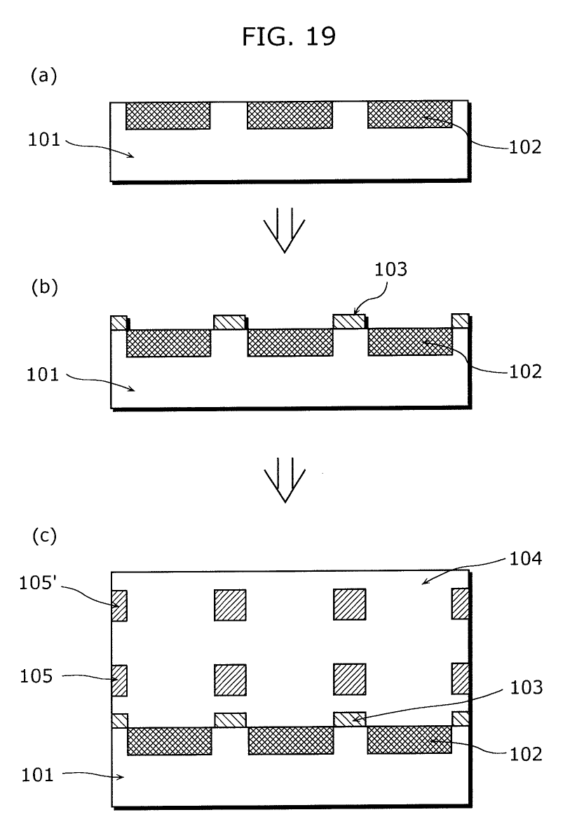

(FIGS. 19 through 23: Manufacturing Method)

The following describes a manufacturing process of the solid-state imaging device in the embodiment with reference to FIGS. 19 through 23. As shown in FIG. 19(a), a photodiode region is formed, for each of pixels, on a surface of the Si substrate 101. Next, as shown in FIG. 19(b), a region for the read-out circuit 103 from the photodiode 102 is formed. Then, as shown in FIG. 19(c), the metal lines 105, and 105′ are formed in the interlayer insulating film 104 made of SiO₂.

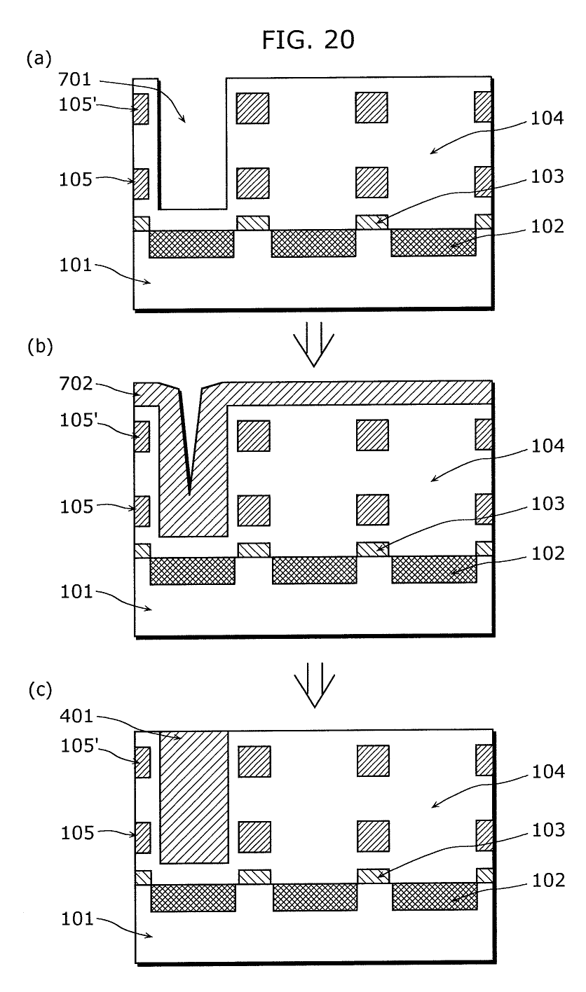

Next, as shown in FIG. 20(a), the opening 701 is formed by dry etching in a red-transmitting optical waveguide forming region above the photodiode 102 including a red pixel. Then, the host resin medium and a solvent including dispersed gold particles are applied to the opening 701 with a spin-coating technique, and sintering is provided at 400° C. Since the opening 701 has a high aspect ratio, this process is repeated twice to completely fill the opening 701 with a sintered object 702. Then, the surface layer is removed by surface polishing to form the red-transmitting optical waveguide 1701 as shown in FIG. 20(c).

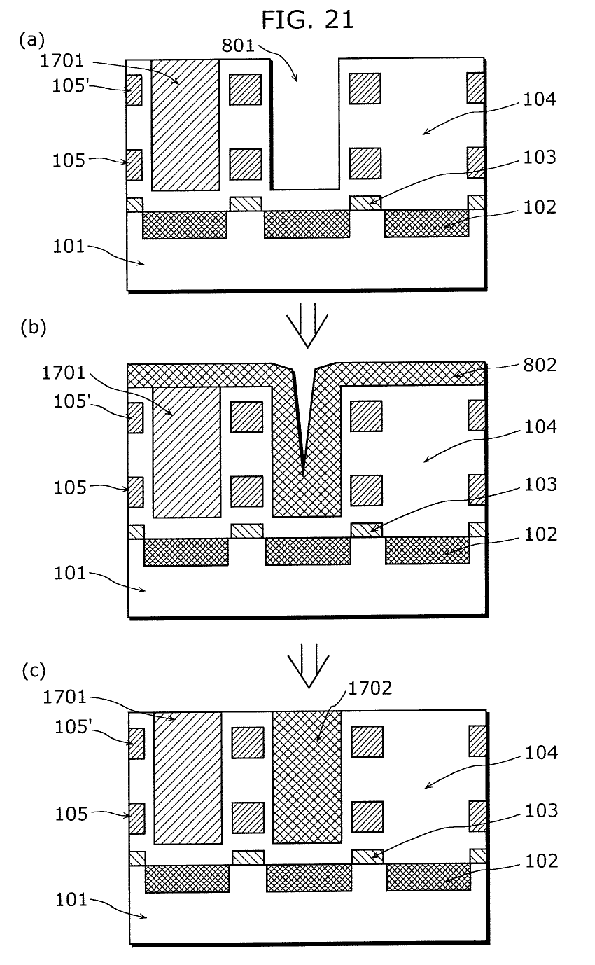

Similarly, as shown in FIG. 21(a), the opening 801 is formed by dry etching in a green-transmitting optical waveguide forming region above the photodiode 102 including a green pixel. Then, the host resin medium and a solvent including dispersed particles having cobalt-titan-nickel-zinc oxides are applied to the opening 801 with the spin-coating technique, and sintering is provided at 400° C. Here, each of the dispersed particles varies between 5 nm and 50 nm (median: 25 nm) in particle diameter. Since the opening 801 has a high aspect ratio, this process is repeated twice to completely fill the opening 801 with the sintered object 802. Then, the surface layer is removed by surface polishing to form the green-transmitting optical waveguide 1702 as shown in FIG. 21(c).

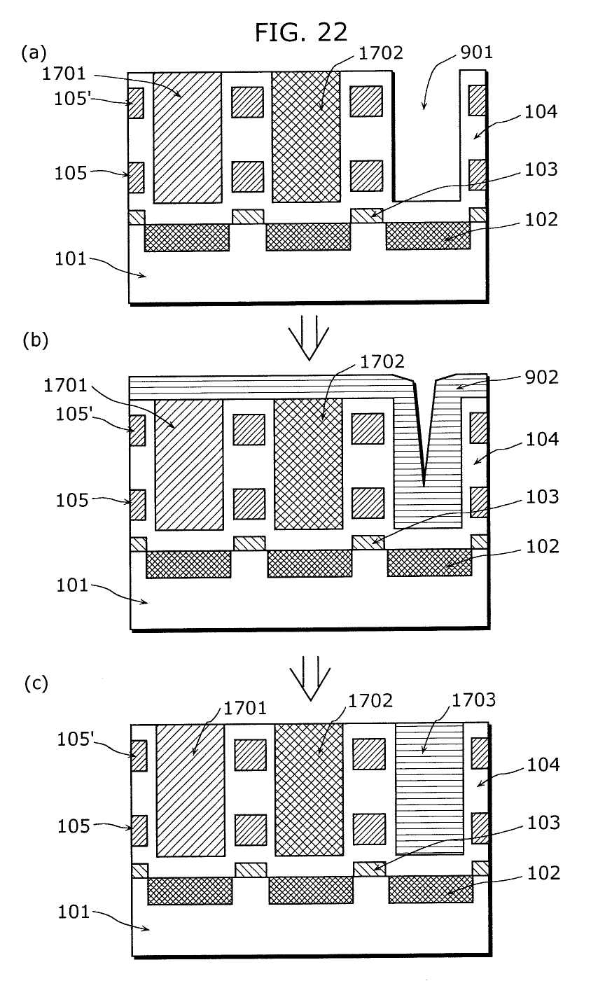

Similarly, as shown in FIG. 22(a), the opening 901 is formed by dry etching in a blue-transmitting optical waveguide forming region above the photodiode 102 including a blue pixel. Then, the host resin medium and a solvent including dispersed cobalt-aluminum oxides are applied to the opening 901 with the spin-coating technique, and sintering is provided at 400° C. Here, each of the dispersed cobalt-aluminum oxides varies between 5 nm and 50 nm (median: 20 nm) in particle diameter. Since the opening 901 has a high aspect ratio, this process is repeated twice to completely fill the opening 901 with the sintered object 902. Then, the surface layer is removed by surface polishing to form the blue-transmitting optical waveguide 1703 as shown in FIG. 22(c).

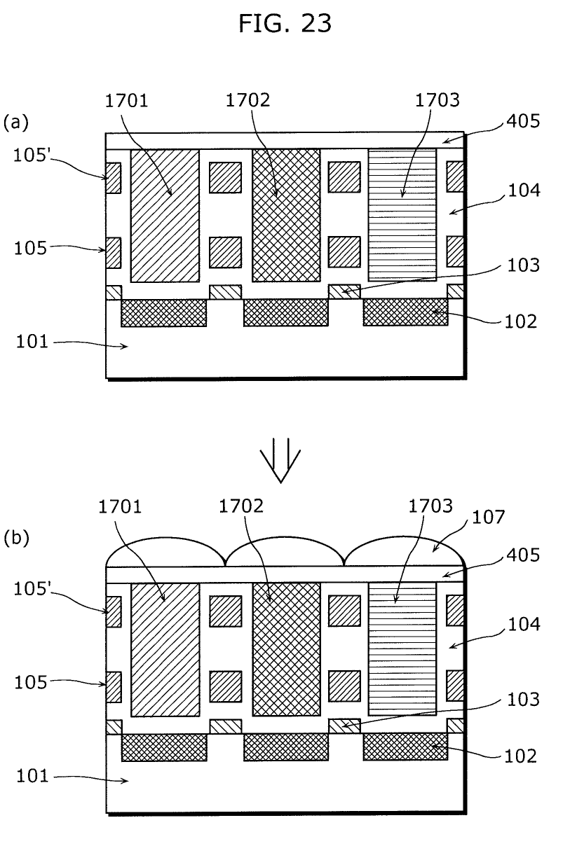

Next, as shown in FIG. 23(a), the planarization insulating film 405 is formed on an outermost surface. After the surface of the planarization insulating film 405 is planarized, as shown in FIG. 23(b), the micro lenses 107 are formed on an outermost surface of the planarization insulating film 405.

It is noted that the optical waveguides may be formed in taper having a wide top and a narrow bottom, or in double-tier having different radiuses.

Further, the combination of the host resin (high-refractive index medium) and the material of the light absorbing particles for the waveguide may be a combination of inorganic materials shown in the first and third embodiments, as well as a combination of organic materials shown in the second embodiment. Since free from oxidation caused by aged deterioration, the combination of inorganic materials does not produce characteristic degradation (color fade-out) when utilized for a color filter.

Moreover, the combination of the host resin (high-refractive index medium) and the material of the light absorbing particles for the waveguide may be a combination of inorganic and organic materials, as well as a combination of organic and inorganic materials. These combinations may be chosen depending on the degree of difficulty in a manufacturing process and a production cost.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

A solid-state imaging device in the present invention can be used for digital cameras including a digital still camera and a video camera, and camera cellular phones, and is suitable for downsizing these appliances and enhancing quality of an image captured thereby.

What is claimed is:

1. A solid-state imaging device including a plurality of photoelectric conversion elements and a plurality of wiring layers, said solid-state imaging device comprising
a plurality of optical waveguide regions each corresponding to and arranged over one of the plurality of photoelectric conversion elements,
wherein a top end of each of said plurality of optical waveguide regions is higher than a top end of at least one of the plurality of wiring layers,
a bottom end of each of said plurality of optical waveguide regions is lower than a bottom end of at least one of the plurality of wiring layers, and
said plurality of optical waveguide regions include a plurality of types of optical waveguide regions each having different light absorbing characteristics.

2. The solid-state imaging device according to claim 1,
wherein each of said plurality of optical waveguide regions further includes:
a high refractive-index medium which has a refractive index higher than a refractive index of a surrounding of said high refractive-index medium, and allows 50% or greater of a light of a light-transmitting wavelength region to transmit; and
light absorbing particles each of which includes metal and has a particle diameter between 5 nm and 50 nm, said light absorbing particles being dispersed in said high refractive-index medium in order to define the light absorbing characteristic.

3. The solid-state imaging device according to claim 2,
wherein said high refractive-index medium is made of an inorganic material, and said light absorbing particles are made of another inorganic material.

4. The solid-state imaging device according to claim 2,
wherein said high refractive-index medium is made of an organic material, and said light absorbing particles are made of another organic material.

5. The solid-state imaging device according to claim 2,
wherein said high refractive-index medium includes:
a medium made of a polymeric material including at least either carbon or silicon, and high refractive-index particles each having a particle diameter between 5 nm and 100 nm, said high refractive-index particles being dispersed in said high refractive-index medium, and made of a material different from a material of said light absorbing particles.

6. The solid-state imaging device according to claim 2,
wherein said high refractive-index medium includes particles each having a particle diameter between 5 nm and 100 nm and being dispersed in said high refractive-index medium, the particles being made of a metal oxide of which material is different from the material of said light absorbing particles.

7. The solid-state imaging device according to claim 2,
wherein said plurality of optical waveguide regions include a first-type, a second-type, and a third-type of optical waveguide regions,
said first-type of optical waveguide region includes at least one of gold particles, copper particles, chromium particles, and iron-chromium oxide particles as said light absorbing particles,
said second-type of optical waveguide region includes at least one of cobalt-titan oxide particles, nickel-titanium-zinc oxide particles, and cobalt-zinc oxide particles as said light absorbing particles, and
said third-type of optical waveguide region includes at least one of cobalt-aluminum oxide particles, and cobalt-chromium oxide particles as said light absorbing particles.

8. The solid-state imaging device according to claim 2,
wherein said plurality of optical waveguide regions include a first-type, a second-type, and a third-type of optical waveguide regions,
said first-type of optical waveguide region includes anthraquinone molecules as said light absorbing particles,
said second-type of optical waveguide region includes copper-phthalocyanine chloride bromide particles as said light absorbing particles, and
said third-type of optical waveguide region includes E-type copper phthalocyanine particles as said light absorbing particles.

9. The solid-state imaging device according to claim 2,
wherein said light absorbing particles, provided in at least one of said plurality of types of optical waveguide regions, include organic molecules.

10. The solid-state imaging device according to claim 1, further comprising
read circuits each of which reads out a signal charge from one of the plurality of photoelectric conversion elements,
wherein an insulating region is formed: between said plurality of optical waveguide regions and the plurality of photoelectric conversion elements; and between said plurality of optical waveguide regions and said read circuit.

11. A manufacturing method for a solid-state imaging device, said manufacturing method comprising:
forming a plurality of photoelectric conversion elements on a semiconductor substrate;
forming a plurality of wiring layers on the semiconductor substrate; and
forming a plurality of optical waveguide regions each corresponding to and arranged over one of the plurality of photoelectric conversion elements,
wherein, in said forming the plurality of optical waveguide regions,
a top end of each of the plurality of optical waveguide regions is higher than a top end of a highest wiring layer out of the plurality of wiring layers,
a bottom end of each of the plurality of optical waveguide regions is lower than: a bottom end of the highest wiring layer; or a bottom end of a wiring layer below the highest wiring layer, and
the plurality of optical waveguide regions includes a plurality of types of optical waveguide regions each having different light absorbing characteristics.
